(19) United States
(12) Patent Application Publication
(10) Pub. No.: US 2025/0391808 A1
(43) Pub. Date: Dec. 25, 2025

(54) WAFER OVERLAY REGISTRATION IN HYBRID BONDING

(71) Applicant: TOKYO ELECTRON LIMITED, Tokyo (JP)

(72) Inventors: Partha MUKHOPADHYAY, Oviedo, FL (US); H. Jim FULFORD, Marianna, FL (US); Anton DEVILLIERS, Albany, NY (US); Mark I. GARDNER, Austin, TX (US); Zuriel CARIBE, Albany, NY (US)

(73) Assignee: TOKYO ELECTRON LIMITED, Tokyo (JP)

(21) Appl. No.: 19/010,838

(22) Filed: Jan. 6, 2025

Related U.S. Application Data
(60) Provisional application No. 63/663,984, filed on Jun. 25, 2024.

(51) Int. Cl. H01L 23/00

(52) U.S. Cl. CPC H01L 24/80; H01L 2224/80006; H01L 2224/8013; H01L 2224/80895; H01L 2224/80896; H01L 2224/80908

(57) ABSTRACT

A method of hybrid bonding includes accessing first dies sourced from a first wafer and second dies sourced from one or more second wafers. First overlay registration values (ORVs) of the first dies and second ORVs of the second dies are measured. A die pairing process is executed that matches the first dies with the second dies to form paired dies based on the first ORVs and the second ORVs. A hybrid bonding process is executed to bond the paired dies.

### INCORPORATION BY REFERENCE

This present disclosure claims the benefit of U.S. Provisional Application No. 63/663,984, filed on Jun. 25, 2024, which is incorporated herein by reference in its entirety. Aspects of the present disclosure are related to Applicant's co-pending application titled “METHOD OF HYBRID BONDING USING DIE DISTRIBUTION MODEL” with Attorney Docket No. 554892US, which is incorporated herein by reference in its entirety.

### FIELD OF THE INVENTION

This disclosure relates generally to semiconductor manufacturing and particularly to packaging and stacking of dies as a technique for transistor stacking or 3D formation of semiconductors.

### BACKGROUND

In the manufacture of a semiconductor device (especially on the microscopic scale), various fabrication processes are executed such as film-forming depositions, etch mask creation, patterning, material etching and removal, and doping treatments. These processes are performed repeatedly to form desired semiconductor device elements on a substrate. Historically, with microfabrication, transistors have been created in one plane, with wiring/metallization formed above the active device plane, and have thus been characterized as two-dimensional (2D) circuits or 2D fabrication. Scaling efforts have greatly increased the number of transistors per unit area in 2D circuits, and yet scaling efforts are running into greater challenges as scaling enters single-digit nanometer semiconductor device fabrication nodes. Semiconductor device fabricators have expressed a desire to continue to improve “power performance, area, cost” or PPAC by implementing three-dimensional integration strategies or “3DI”. Many of these strategies employ stacking, such as die to die, die to wafer, and wafer to wafer for 3DI of circuits, transistors, memory cells, and interconnections between them.

### SUMMARY

The present disclosure relates to a method of hybrid bonding and an apparatus of executing the same.

According to a first aspect of the disclosure, a method of hybrid bonding is provided. The method includes accessing first dies sourced from a first wafer and second dies sourced from one or more second wafers. First overlay registration values (ORVs) of the first dies and second ORVs of the second dies are measured. A die pairing process is executed that matches the first dies with the second dies to form paired dies based on the first ORVs and the second ORVs. A hybrid bonding process is executed to bond the paired dies.

In some embodiments, the executing the die pairing process includes, for each first die having a respective first ORV, picking a respective second die having a respective second ORV and, onto each first die, placing the respective second die. A difference between the respective first ORV and the respective second ORV is within a threshold.

In some embodiments, before the executing the die pairing process, a plurality of the second dies are sourced from a common second wafer and have initial relative positions with regard to each other. After the executing the die pairing process, the plurality of the second dies are placed on respective first dies and have changed relative positions with regard to each other.

In some embodiments, two neighboring second dies, which are sourced from the common second wafer before the executing the die pairing process, are not neighboring to each other after the executing the die pairing process.

In some embodiments, the respective second die is picked from a dicing tape.

In some embodiments, the first dies are divided into groups based on the first ORVs. The second dies are divided into groups based on the second ORVs. A group matching process is executed that matches a group of the first dies with a group of the second dies.

In some embodiments, the executing the die pairing process includes picking one of the group of the second dies and placing the one of the group of the second dies onto one of the group of the first dies.

In some embodiments, respective first ORVs of the group of the first dies and respective second ORVs of the group of the second dies are within a predetermined range.

In some embodiments, the group of the second dies is sourced from a single second wafer.

In some embodiments, the group of the second dies is sourced from a plurality of second wafers.

In some embodiments, the first wafer is flattened before the first ORVs of the first dies are measured. The one or more second wafers are flattened before the second ORVs of the second dies are measured.

In some embodiments, the first ORVs of the first dies and the second ORVs of the second dies are measured by optical imaging, optical scatterometry, scanning electron microscopy or a combination thereof.

In some embodiments, the measuring includes mapping the first OR Vs across the first wafer and mapping the second ORVs across the one or more second wafers.

In some embodiments, the first wafer and each of the one or more second wafers have a different ORV distribution.

In some embodiments, the first wafer and the one or more second wafers have a same wafer diameter.

In some embodiments, the paired dies include all of the first dies.

In some embodiments, the paired dies include all of the second dies, and the second dies are sourced from a single second wafer.

In some embodiments, the paired dies include a subset of the second dies, and the second dies are sourced from a plurality of second wafers.

In some embodiments, the hybrid bonding process is executed so that respective dielectric materials of the first dies and the second dies bond with each other and respective metal materials of the first dies and the second dies expand to bond with each other.

According to a second aspect of the disclosure, an apparatus is provided. The apparatus includes a controller including a processor that is programmed to access first dies sourced from a first wafer and second dies sourced from one or more second wafers, measure first overlay registration values (ORVs) of the first dies and second ORVs of the second dies, execute a die pairing process that matches the first dies with the second dies to form paired dies based on the first ORVs and the second ORVs, and execute a hybrid bonding process to bond the paired dies.

Note that this summary section does not specify every embodiment and/or incrementally novel aspect of the present disclosure or claimed invention. Instead, this summary only provides a preliminary discussion of different embodiments and corresponding points of novelty. For additional details and/or possible perspectives of the invention and embodiments, the reader is directed to the Detailed Description section and corresponding figures of the present disclosure as further discussed below.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be increased or reduced for clarity of discussion.

FIG. 1 shows a flow chart of a process for manufacturing a semiconductor device, in accordance with some embodiments of the present disclosure.

FIG. 2A shows a top view of a top wafer in accordance with some embodiments of the present disclosure.

FIG. 2B shows a top view of a bottom wafer in accordance with some embodiments of the present disclosure.

FIG. 2C shows a schematic view of a die pairing process in accordance with some embodiments of the present disclosure.

FIG. 3 shows a schematic view of a die pairing process in accordance with some embodiments of the present disclosure.

FIG. 4 shows a flow chart of a process for manufacturing a semiconductor device, in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This in repetition is for the purpose of simplicity and clarity and does not in itself dictate a relationship between the various embodiments and/or configurations discussed. Further, spatially relative terms, such as “top,” “bottom,” “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The order of discussion of the different steps as described herein has been presented for clarity's sake. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present invention can be embodied and viewed in many different ways.

In the drawings, like reference numerals designate identical or corresponding parts throughout the several views. Additionally, as used herein, the words “a”, “an” and the like generally carry a meaning of “one or more”, unless stated otherwise.

Furthermore, the terms, “approximately”, “approximate”, “about” and similar terms generally refer to ranges that include the identified value within a margin of 20%, 10%, or preferably 5%, and any values therebetween.

A numerical range represented by “to” includes numerical values at both ends, unless specified otherwise.

Power, Performance, Area, and Cost (PPAC) improvements and Moore's Law's logarithmic performance increases in semiconductor devices have historically progressed primarily through aggressive doubling of transistor count every 18 months enabled by dimensional shrink without regard to functional chip type or the proper management of power scaling and heat dissipation. In the past two decades, as the industry has moved away from fully integrated large silicon area systems on chip (SoCs), it has become increasingly important for continual improvement in semiconductor devices to develop via optimizing PPAC at the system integration level through advanced packaging technologies. These technologies enable different functional chip types (such as “chiplets”) to be integrated into a single package and/or memory chips to be stacked vertically along with controller devices.

An important packaging technology for meeting the industry's ever-increasing needs is hybrid bonding. Hybrid bonding involves bonding a die to a die, or a die to a wafer, or a wafer to a wafer, in which both dielectric material and conductive material are exposed/uncovered and bonded to like materials on opposing substrates. Thus, opposing dielectric surfaces are bonded together, and then opposing metals are bonded together. The result is that there are dielectric-dielectric bonds as well as metal-metal bonds. This hybrid bonding technique is typically executed to bond wiring levels or structures together from two dies (or wafers). The bonding process involves annealing which results in expansion of the metal. For example, copper electrical connections and dielectric insulating materials on singulated dies or full wafers can be bonded face-to-face onto substrate dies or wafers, referred to as die-to-die (D2D), die-to-wafer (D2 W) or wafer-to-wafer (W2 W) hybrid bonding. After hybrid bonding, a substrate wafer can then be singulated to produce packaged modules.

A common issue encountered during the die/wafer bonding process is the misalignment of dies/wafers. This is often a result of the wafer bow needing to be flattened by means of stress or strain on the sample. After flattening, the registration of the wafer can become inhomogeneous. It can get elongated in any direction, potentially leading to die bonding failure irrespective of correction in alignment. As a result, the whole die can't be perfectly aligned, creating a registration mismatch between the two dies/wafers. Such misalignment can lead to defects in the circuit, affecting the performance and yield of the semiconductor devices.

Another problem arises when the registration is not taken care of. It may match at the center of the die, but it will be off at the edge of the die. Registration, e.g. the x and y dimensions, changes due to the stress during the flattening process, thereby changing the registration at the edge. This can lead to defects in the circuit, affecting the performance and yield of the semiconductor devices. Therefore, proper overlay registration is important for ensuring that the features on the top die are correctly positioned relative to the features of the underlying diel layers of the bottom die.

As device geometries shrink with advanced technology nodes, the tolerance for overlay errors becomes even smaller, necessitating more precise alignment. High precision in overlay registration improves the overall yield of functional devices from a wafer. Therefore, there is a need to overcome the problems discussed above. There is a need for a more effective method to ensure precise alignment during the die bonding process, taking into account the wafer registration, overlay registration, and potential for misalignment.

Techniques herein provide a method and an apparatus for enhancing the yield of functional devices from a wafer. This can be achieved by flattening a wafer sample, registering the flattened wafer, and calculating an overlay registration for each die in the wafer. A feedback control system with a decision-making algorithm can then be employed to distribute a second die over a first die based on the calculated overlay registration. The process further involves performing pick-and-place die-to-chip bonding using the distributed second die and the first die and enhancing the yield in alignment during the bonding process by matching the overlay registration. The apparatus may incorporate a smart die bonder with an artificial intelligence (AI) engine to optimize the distribution based on the failure analysis of a previous bonding database. This novel and efficient approach significantly improves the overall yield of functional devices, ensuring precise alignment and reducing overlay errors.

According to aspects of the present disclosure, a control system in the form of a decision-making algorithm can consider the overlay registration of each bottom die in the whole bottom/substrate wafer and distribute top dies by matching the overlay registration in the pick-and-place die-to-chip bonding. This (feedback) control system can be employed to achieve the required precision in overlay registration. The decision-making algorithm in a smart die bonder can input the overlay registration and distribute the top dies on the bottom dies by matching the overlay registration to optimize the yield in alignment during the pick-and-place die-to-chip bonding. For instance, a top die can be an individual die. A bottom die can be an individual die or part of a full wafer. The AI engine in the smart bonder may also consider total Cu recess gap distribution along with registration mismatch between the two dies as disclosed in Applicant's co-pending application titled “METHOD OF HYBRID BONDING USING DIE DISTRIBUTION MODEL” with Attorney Docket No. 554892US, which is incorporated herein by reference in its entirety, and optimize the pick-and-place matching distribution based on the failure analysis of the previous bonding database. This approach can allow misalignment to successful bonding with considerable contact resistance and enhanced yield.

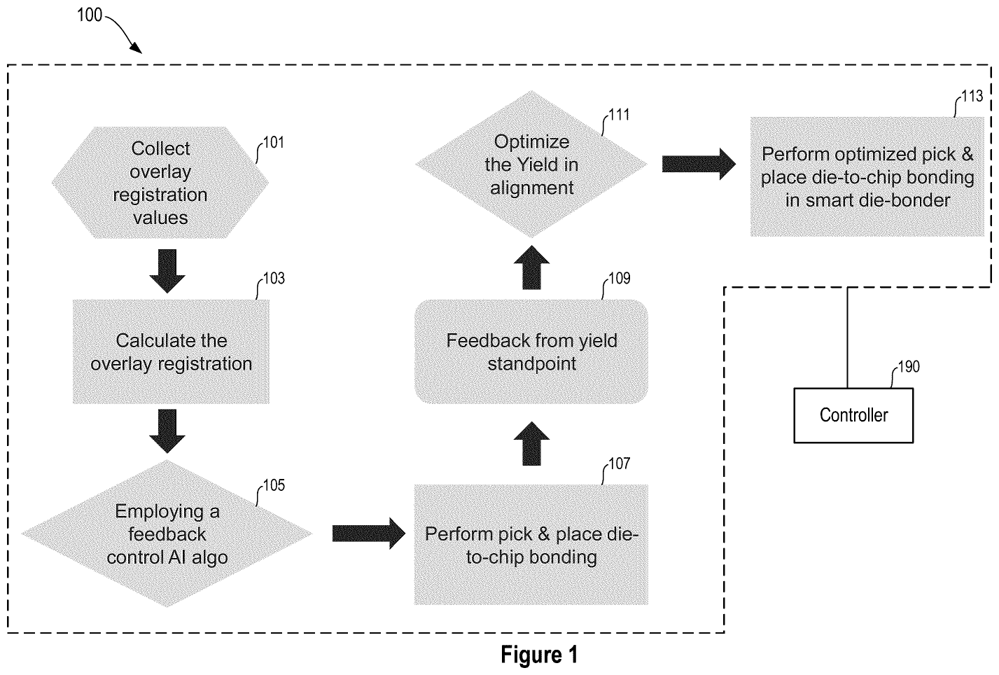

FIG. 1 shows a flow chart of a process 100 for hybrid bonding, in accordance with some embodiments of the present disclosure. In shape 101, overlay registration values of a bottom wafer and one or more top wafers are collected. In shape 103, the overlay registration is calculated for the bottom wafer and the one or more top wafers. In shape 105, a feedback control artificial intelligence (AI) algorithm can be employed to pair bottom dies sourced from the bottom wafer with top dies sourced from the one or more top wafers. In shape 107, a pick-and-place die-to-chip bonding process can be performed. For instance, a respective top die is picked for and placed onto each bottom die based on the calculated overlay registration. In shape 109, feedback is obtained from a yield standpoint. In shape 111, the yield in alignment is optimized. In shape 113, an optimized pick-and-place die-to-chip bonding process is performed in a smart die-bonder.

Optionally, a controller 190 may be coupled to various components of the process 100 to receive inputs from and provide outputs to the components. For example, the controller 190 can be configured to implement shapes 101, 103, 105, 107, 109, 111 and/or 113. Of course, one or more functions of the controller 190 can also be manually accomplished.

In some embodiments, the controller 190 may include a memory storage unit and user interface (all not shown). Components of a semiconductor processing tool (e.g. a bonding tool, a registration metrology tool, etc.) can be connected to and controlled by the controller 190. Various wafer-processing operations can be executed via the user interface, and various wafer processing recipes and operations can be stored in the storage unit.

It will be recognized that the controller 190 may be coupled to various components of various semiconductor processing tools to receive inputs from and provide outputs to the various components. For example, the controller 190 can be configured to receive overlay registration data from a corresponding registration metrology tool. The controller 190 can also be configured to pick a top die from a dicing tape and place the top die onto a bottom die by controlling a robotic arm. The controller 190 can further be configured to adjust knobs and control settings for the corresponding bonding tool. Of course such adjustments can be manually made as well.

The controller 190 can be implemented in a wide variety of manners. In one example, the controller 190 includes a computer. In another example, the controller 190 includes one or more programmable integrated circuits that are programmed to provide the functionality described herein. For example, one or more processors (e.g. microprocessor, microcontroller, central processing unit, etc.), programmable logic devices (e.g. complex programmable logic device (CPLD)), field programmable gate array (FPGA), etc.), and/or other programmable integrated circuits can be programmed with software or other programming instructions to implement the functionality of a semiconductor processing recipe. It is further noted that the software or other programming instructions can be stored in one or more non-transitory computer-readable mediums (e.g. memory storage devices, FLASH memory, DRAM memory, reprogrammable storage devices, hard drives, floppy disks, DVDs, CD-ROMs, etc.), and the software or other programming instructions when executed by the programmable integrated circuits cause the programmable integrated circuits to perform the processes, functions, and/or capabilities described herein. Other variations could also be implemented.

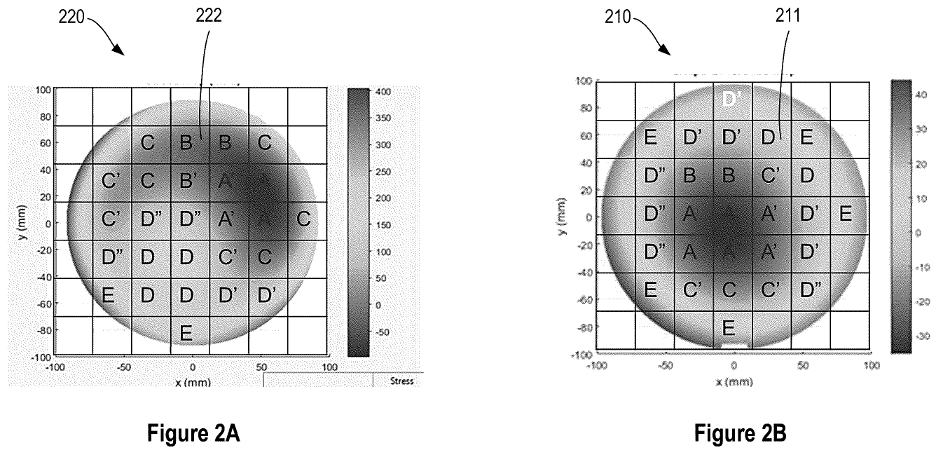

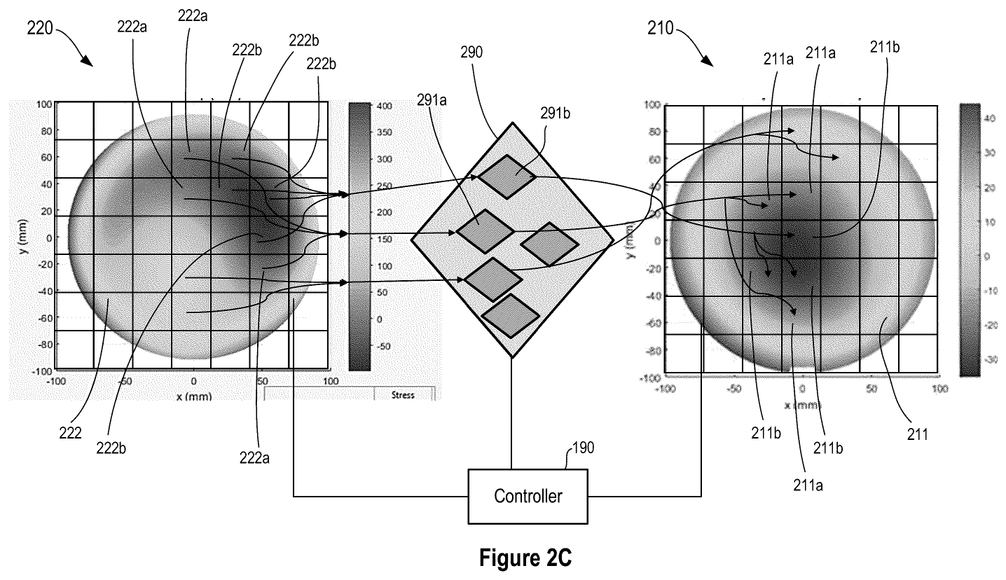

FIG. 2A shows a top view of a top wafer (also referred to as a second wafer 220 hereinafter), and FIG. 2B shows a top view of a bottom wafer (also referred to as a first wafer 210), in accordance with some embodiments of the present disclosure.

The first wafer 210 includes a plurality of first dies 211 arranged in a grid pattern. The first wafer 210 can be flattened to reduce wafer bow. As a result, wafer registration can become inhomogeneous. First overlay registration values (ORVs) of the first dies 211 can be measured by a registration metrology technique including, but not limited to, optical imaging, optical scatterometry, scanning electron microscopy and/or the like. As a result, the first ORVs can be mapped across the first wafer 210. The first dies 211 can be divided into groups based on respective first ORVs.

In the example of FIG. 2B, the first dies 211 can be divided into Group A, Group A′, Group B, Group B′, Group C, Group C′, Group D, Group D′, Group D″ and Group E, where each group may include one or more of the first dies 211. Respective dies within each group have respective first ORVs that are close to each other, e.g. within a predetermined range.

The second wafer 220 includes a plurality of second dies 222 arranged in a grid pattern. The second wafer 220 can be flattened to reduce wafer bow. As a result, wafer registration can become inhomogeneous. Second ORVs of the second dies 222 can be measured by the same registration metrology technique as the first ORVs or different registration metrology techniques. As a result, the second ORVs can be mapped across the second wafer 220. The second dies 222 can be divided into groups based on respective second ORVs. The first wafer 210 and the second wafer 220 can have different ORV distributions in practice, although it is also possible that the first wafer 210 and the second wafer may have the same ORV distribution.

In the example of FIG. 2A, the second dies 222 can be divided into Group A, Group A′, Group B, Group B′, Group C, Group C′, Group D, Group D′, Group D″ and Group E, where each group may include one or more of the second dies 222. Respective dies within each group have second ORVs that are close to each other, e.g. within a predetermined range.

Here, groups of the first dies 211 and groups of the second dies 222 are designated the same letter for having the same or similar ORVs. For instance, respective first ORVs of Group A of the first dies 211 are within a first range while respective second ORVs of Group A of the second dies 222 are within a second range. The first range and the second range can be the same as each other or close to each other such that Group A of the first dies 211 and Group A of the second dies 222 can be treated as having substantially the same ORVs for subsequent processing. Similarly, Group B of the first dies 211 and Group B of the second dies 222 can be treated as having substantially the same ORVs for subsequent processing. More generally speaking, allowable registration matching could be A to A/A′, or B to B/B′, C to C/C′, or D to D/D′/D″, etc. On the other hand, pairing a die from Group B of the second dies 222 with a die from Group A or A′ of the first dies 211 can lead to misalignment and failure of device operation of die-to-chip. This would be more problematic as feature sizes are going down.

Note that FIGS. 2A and 2B only show one embodiment of dividing the first dies 211 and/or the second dies 222 into groups for illustrative purposes. In other embodiments, depending on specific design needs, the first dies 211 and/or the second dies 222 can be divided into groups differently, for example as will be demonstrated in FIG. 2C.

FIG. 2C shows a schematic view of a die pairing process in accordance with some embodiments of the present disclosure. Herein, the first dies 211 are divided into a first group represented by first dies 211a, a second group represented by first dies 211b, and other groups based on respective first ORVs. The respective first ORVs of the first dies 211 can be measured for example by the aforementioned registration metrology technique, which may further be controlled by the controller 190 and stored in the controller 190.

The controller 190 can include a decision-making algorithm 290 that stores ORV values and/or ranges (e.g. 291a, 291b, etc.) corresponding to groups of the first dies (e.g. 211a, 211b, etc.). The controller 190 can also measure and store respective second ORVs of the second dies 222. The decision-making algorithm 290 can compare the (stored) ORV ranges (e.g. 291a, 291b, etc.) with the second ORVs and accordingly divide the second dies 222 into a first group represented by second dies 222a, a second group represented by second dies 222b, and other groups. For instance, the first group of the first dies represented by the first dies 211a and the first group of the second dies represented by the second dies 222a can be matched and paired for having respective ORVs within a first ORV range 291a. The second group of the first dies represented by the first dies 211b and the second group of the second dies represented by the second dies 222b can be matched and paired for having respective ORVs within a second ORV range 291b.

As a result, any one of the second dies 222a can be picked from the second wafer 220 and placed onto any one of the first dies 211a to form a respective pair for example by a robotic arm controlled by the controlled 190. Similarly, any one of the second dies 222b can be picked from the second wafer 220 and placed onto any one of the first dies 211b to form a respective pair.

In this example, the first dies 211 can be used as bottom dies while the second dies 222 can be used as top dies. That is, the second dies 222 are flipped upside down and placed on top of the first dies 211 so that the first dies 211 and the second dies 222 are oriented face to face. For example, a face side (e.g. circuitry) of the first dies 211 and a face side (e.g. circuitry) of the second dies 222 face towards each other while a back side (e.g. bulk semiconductor material) of the first dies 211 and a back side (e.g. bulk semiconductor material) of the second dies 222 face away from each other.

Note that the second dies 222 have initial relative positions with regard to each other on the second wafer 220. However, after die pairing or a pick-and-place process, the second dies 222 are placed on respective first dies 211 and may have changed relative positions with regard to each other. For instance, two neighboring second dies 222 on the second wafer 220 may not be neighboring to each other after the pick-and-place process.

In the examples of FIGS. 2A-2C, the first wafer 210 and the second wafer 220 both have a wafer diameter of 200 mm. Generally speaking, the first wafer 210 and the second wafer 220 may each independently have a wafer diameter of 50 mm, 75 mm, 100 mm, 125 mm, 150 mm, 200 mm, 300 mm or 450 mm. Preferably, the first wafer 210 and the second wafer 220 each independently have a wafer diameter of 150 mm, 200 mm or 300 mm. Additionally, the first wafer 210 and the second wafer 220 may or may not have a same wafer diameter.

Note that dimensions of various wafer diameters are mentioned herein merely for illustrative purposes and are not limiting. As a skilled artisan would understand, wafer diameters can also be expressed in inches, and a value expressed in millimeters and a value expressed in inches for a same wafer are not always equal to each other. For instance, 50 mm, 75 mm, 100 mm, 125 mm, 150 mm, 200 mm, 300 mm and 450 mm may respectively be known as 2 inches, 3 inches, 4 inches, 5 inches, 6 inches, 8 inches, 12 inches and 18 inches. However, 300 mm=11.811 inches, not exactly 12 inches. 200 mm=7.874 inches, not exactly 8 inches. Therefore, a value of a wafer diameter in the present disclosure generally represents a range of the value*(100%±10%), preferably the value*(100%±5%), preferably the value*(100%±3%), preferably the value. For instance, a wafer diameter of 200 mm represents a range of 180 mm to 220 mm, preferably 190 mm to 210 mm, preferably 194 mm to 206 mm, preferably 200 mm.

In a non-limiting example, a plasma activation process can be performed on the first dies 211 and the second dies 222, and deionized water (DIW) may be used to rinse the first dies 211 and the second dies 222. Then the first dies 211 and the second dies 222 can be aligned and pre-bonded. Pre-bonded dies may be inspected, for example using infrared light transmission imaging, and can be stripped and cleaned. The pre-bonded dies can further be bonded for instance by an annealing process. As a result, respective dielectric materials of the first dies 211 and the second dies 222 bond with each other and respective metal materials of the first dies 211 and the second dies 222 expand to bond with each other. Detailed explanations are disclosed in Applicant's co-pending application, titled “METHOD OF HYBRID BONDING USING DIE DISTRIBUTION MODEL” with Attorney Docket No. 554892US, which is incorporated herein by reference in its entirety. It should be understood that the first dies 211 and the second dies 222 may alternatively be bonded by other processes or techniques such as direct bonding, surface-activated bonding, plasma-activated bonding, anodic bonding, eutectic bonding, glass frit bonding, adhesive bonding, reactive bonding, transient liquid phase diffusion bonding, and/or the like.

In the example of FIG. 2C, there are three of the first dies 211a and three of the first dies 211b while there are three of the second dies 222a and four of the second dies 222b. Therefore, the first dies 211a and the first dies 211b can each find a respective match from dies sourced from the second wafer 220 to form a respective pair. In other examples, the second dies 222a may be fewer than the first dies 211a. Additionally or alternatively, the second dies 222b may be fewer than the first dies 211b. Accordingly, one or more additional second wafers may be needed to provide dies for the first dies 211a and/or the first dies 211b. In some embodiments, one or more of the first dies 211 may have respective first ORVs that cannot be matched or paired with any of the second dies 222. Accordingly, one or more additional second wafers will be needed.

Referring back to FIGS. 2A and 2B, there are four dies in Group A, two dies in Group A′, two dies in Group B, zero die in Group B′, one die in Group C, two dies in Group C′, two dies in Group D, five dies in Group D′, four dies in Group D″ and five dies in Group E in the first dies 211. There are two dies in Group A, two dies in Group A′, two dies in Group B, one die in Group B′, four dies in Group C, three dies in Group C′, four dies in Group D, two dies in Group D′, three dies in Group D″ and two dies in Group E in the second dies 222. Therefore, not all of the first dies 211 can find a match with the second dies 222. Accordingly, one or more additional second wafers will be needed.

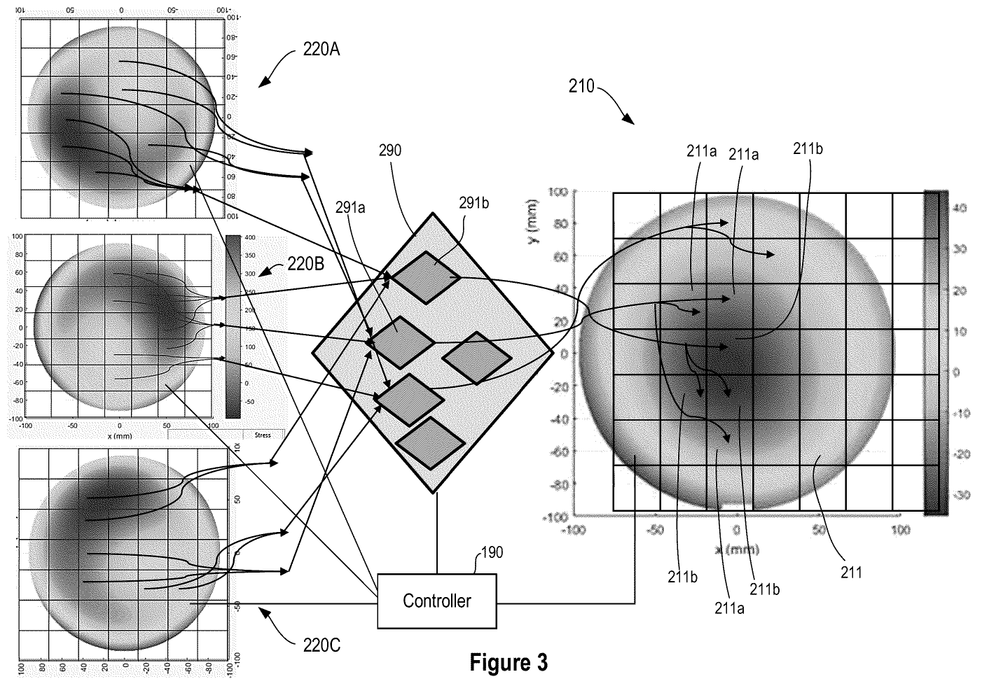

FIG. 3 shows a schematic view of a die pairing process in accordance with some embodiments of the present disclosure. Herein, a plurality of second wafers for example represented by 220A, 220B and 220C are used to provide top dies for the first dies 211 sourced from the first wafer 210. For instance, one or more dies, which have respective ORVs that fall within the first ORV range 291a, can be sourced from each of the second wafers 220A, 220B and 220C and paired with the first dies 211a. Similarly, one or more dies, which have respective ORVs that fall within the second ORV range 291b, can be sourced from each of the second wafers 220A, 220B and 220C and paired with the first dies 211b.

Here, there are four dies in Group A, two dies in Group A′, two dies in Group B, zero die in Group B′, one die in Group C, two dies in Group C′, two dies in Group D, five dies in Group D′, four dies in Group D″ and five dies in Group E in the first dies 211. There are six dies in Group A, six dies in Group A′, six dies in Group B, three dies in Group B′, twelve dies in Group C, nine dies in Group C′, twelve dies in Group D, six dies in Group D′, nine dies in Group D″ and six dies in Group E for the second wafers 220A, 220B and 220C. Therefore, each of the first dies 211 can find a respective match with dies sourced from the second wafers 220A, 220B and 220C.

The controller 190 can be configured to measure respective second ORVs of second dies sourced from the second wafers 220A, 220B and 220C and store the respective second ORVs. The decision-making algorithm 290 can compare the ORV ranges (e.g. 291a, 291b, etc.) with the second ORVs and accordingly divide second dies sourced from the second wafers 220A, 220B and 220C into groups to match and pair with the first dies 211.

Note that the drawings of the present disclosure are not necessarily drawn to scale. Particularly in the example of FIG. 3, the first wafer 210 and the second wafers 220A, 220B and 220C all have a same wafer diameter of 200 mm. Generally speaking, the first wafer 210 and the second wafers 220A, 220B and 220C may each independently have a wafer diameter of 50 mm, 75 mm, 100 mm, 125 mm, 150 mm, 200 mm, 300 mm or 450 mm. Preferably, the first wafer 210 and the second wafers 220A, 220B and 220C each independently have a wafer diameter of 150 mm, 200 mm or 300 mm. Additionally, the first wafer 210 and the second wafers 220A, 220B and 220C may or may not have a same wafer diameter. In this example, the second wafers 220A, 220B and 220C have the same ORV distribution. In other examples, the second wafers 220A, 220B and 220C can have different ORV distributions.

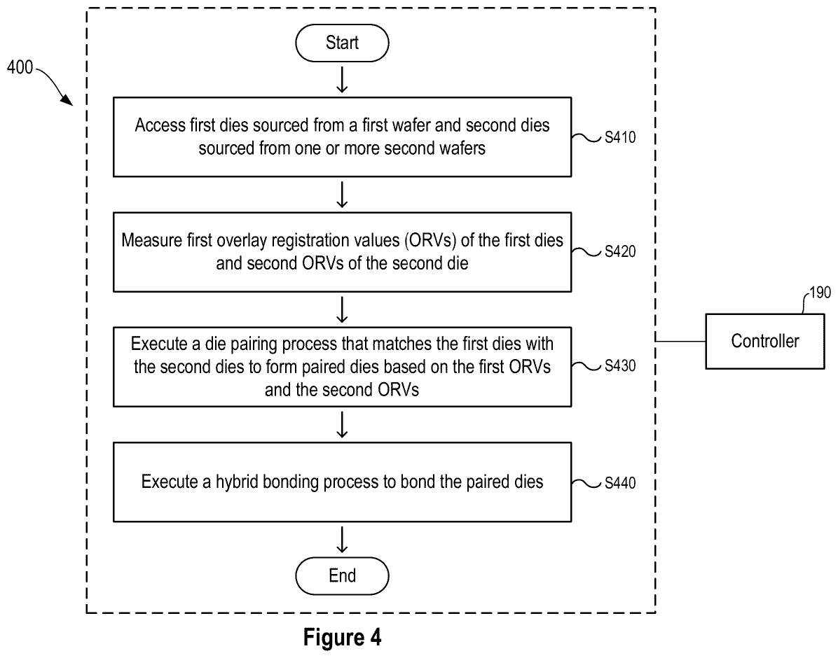

FIG. 4 shows a flow chart of a process 400 of hybrid bonding, in accordance with some embodiments of the present disclosure. At step S410, first dies sourced from a first wafer and second dies sourced from one or more second wafers are accessed. At step S420, first overlay registration values (ORVs) of the first dies and second ORVs of the second dies are measured. At step S430, a die pairing process is executed that matches the first dies with the second dies to form paired dies based on the first ORVs and the second ORVs. At step S440, a hybrid bonding process is executed to bond the paired dies.

It will also be recognized that the controller 190 may be coupled to various components of the process 400 to receive inputs from and provide outputs to the components. For example, the controller 190 can be configured to implement steps S410, S420, S430 and/or S440. Of course, one or more functions of the controller 190 can also be manually accomplished.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“Substrate” or “wafer” as used herein generically refers to an object being processed in accordance with the invention. The substrate may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

The substrate can be any suitable substrate, such as a silicon (Si) substrate, a germanium (Ge) substrate, a silicon-germanium (SiGe) substrate, and/or a silicon-on-insulator (SOI) substrate. The substrate may include a semiconductor material, for example, a Group IV semiconductor, a Group III-V compound semiconductor, or a Group II-VI oxide semiconductor. The Group IV semiconductor may include Si, Ge, or SiGe. The substrate may be a bulk wafer or an epitaxial layer.

Those skilled in the art will also understand that there can be many variations made to the operations of the techniques explained above while still achieving the same objectives of the invention. Such variations are intended to be covered by the scope of this disclosure. As such, the foregoing descriptions of embodiments of the invention are not intended to be limiting. Rather, any limitations to embodiments of the invention are presented in the following claims.

What is claimed is:

1. A method of hybrid bonding, the method comprising:
accessing first dies sourced from a first wafer and second dies sourced from one or more second wafers;
measuring first overlay registration values (ORVs) of the first dies and second ORVs of the second dies;
executing a die pairing process that matches the first dies with the second dies to form paired dies based on the first ORVs and the second ORVs; and
executing a hybrid bonding process to bond the paired dies.

2. The method of claim 1, wherein the executing the die pairing process comprises:
for each first die having a respective first ORV, picking a respective second die having a respective second ORV, wherein a difference between the respective first ORV and the respective second ORV is within a threshold; and
onto each first die, placing the respective second die.

3. The method of claim 2, wherein:
before the executing the die pairing process, a plurality of the second dies are sourced from a common second wafer and have initial relative positions with regard to each other, and
after the executing the die pairing process, the plurality of the second dies are placed on respective first dies and have changed relative positions with regard to each other.

4. The method of claim 3, wherein:
two neighboring second dies, which are sourced from the common second wafer before the executing the die pairing process, are not neighboring to each other after the executing the die pairing process.

5. The method of claim 2, wherein:
the respective second die is picked from a dicing tape.

6. The method of claim 1, further comprising:
dividing the first dies into groups based on the first ORVs;
dividing the second dies into groups based on the second ORVs; and
executing a group matching process that matches a group of the first dies with a group of the second dies.

7. The method of claim 6, wherein the executing the die pairing process comprises:
picking one of the group of the second dies; and
placing the one of the group of the second dies onto one of the group of the first dies.

8. The method of claim 6, wherein:
respective first ORVs of the group of the first dies and respective second ORVs of the group of the second dies are within a predetermined range.

9. The method of claim 6, wherein:
the group of the second dies is sourced from a single second wafer.

10. The method of claim 6, wherein:
the group of the second dies is sourced from a plurality of second wafers.

11. The method of claim 1, further comprising:
flattening the first wafer before the first ORVs of the first dies are measured; and
flattening the one or more second wafers before the second ORVs of the second dies are measured.

12. The method of claim 1, wherein:
the first ORVs of the first dies and the second ORVs of the second dies are measured by optical imaging, optical scatterometry, scanning electron microscopy or a combination thereof.

13. The method of claim 1, wherein:
the measuring comprises mapping the first ORVs across the first wafer and mapping the second ORVs across the one or more second wafers.

14. The method of claim 13, wherein:
the first wafer and each of the one or more second wafers have a different ORV distribution.

15. The method of claim 1, wherein:
the first wafer and the one or more second wafers have a same wafer diameter.

16. The method of claim 1, wherein:
the paired dies include all of the first dies.

17. The method of claim 16, wherein:
the paired dies include all of the second dies, and
the second dies are sourced from a single second wafer.

18. The method of claim 16, wherein:
the paired dies include a subset of the second dies, and
the second dies are sourced from a plurality of second wafers.

19. The method of claim 1, wherein:
the hybrid bonding process is executed so that respective dielectric materials of the first dies and the second dies bond with each other and respective metal materials of the first dies and the second dies expand to bond with each other.

20. An apparatus, comprising:
a controller including a processor that is programmed to:
access first dies sourced from a first wafer and second dies sourced from one or more second wafers;
measure first overlay registration values (ORVs) of the first dies and second ORVs of the second dies;
execute a die pairing process that matches the first dies with the second dies to form paired dies based on the first ORVs and the second ORVs; and
execute a hybrid bonding process to bond the paired dies.
